(19) United States
(12) Patent Application Publication
(10) Pub. No.: US 2009/0095991 A1
(43) Pub. Date: Apr. 16, 2009

(54) METHOD OF FORMING STRAINED MOSFET DEVICES USING PHASE TRANSFORMABLE MATERIALS

(75) Inventor: Kangguo Cheng, Guilderland, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/870,524

(22) Filed: Oct. 11, 2007

(51) Int. Cl. H01L 21/336; H01L 29/78

(52) U.S. Cl. 257/288; 438/197; 257/E21.409; 257/E29.255

(57) ABSTRACT

A method of forming a strained metal oxide semiconductor field effect transistor (MOSFET) device includes forming a gate conductor and gate insulator layer over a semiconductor substrate; forming source and drain regions in the semiconductor substrate, thereby defining the MOSFET device; forming a phase transformable material layer over the MOSFET device, wherein the phase transformable layer is in a first phase upon initial formation thereof, and following the initial formation of the phase transformable material layer, converting the phase transformable layer from the first phase to a second phase, wherein the second phase results in the phase transformable layer applying a longitudinal stress on a channel of the MOSFET device.

### BACKGROUND

The present invention relates generally to semiconductor device processing techniques, and, more particularly, to a method of forming strained metal oxide semiconductor field effect transistor (MOSFET) devices using phase transformable materials.

Conventional gate length and gate dielectric scaling of complementary metal oxide semiconductor (CMOS) technology no longer produces the desired improvements in device performance. Parasitic resistances and capacitances are becoming a fundamental limiting factor to improving device performance with each new technology mode. New materials and device architectures are thus required in order to overcome these fundamental scaling obstacles that degrade device performance.

One approach to overcome these effects is to increase the drive current of MOSFETs by increasing the mobility of the carriers in the channel. It is well known that the application of mechanical stress can substantially improve or degrade the mobility of electrons and holes in a semiconductor. However, it is also known that electrons and holes respond differently to the same type of stress. For example, the application of compressive stress in the longitudinal direction of current flow is beneficial for hole mobility, but detrimental for electron mobility. On the other hand, the application of tensile stress in the longitudinal direction is beneficial for electrons, but detrimental for holes.

State of the art technology currently uses stress nitride liners that are deposited after silicide formation to apply longitudinal stress to the channel and therefore increase the current drive of CMOS devices. However, it is imperative to develop an integration scheme that allows the desired application of stress (compressive or tensile) on the appropriate devices (NFETs or PFETs) to maximize performance of CMOS technology. Unfortunately, the use of existing nitride stress liners appears to be approaching limitations in the magnitude of stress that can be applied to the channel of CMOS devices. More recently, embedded SiGe layers have also been used to provide compressive stress in the PFET regions of a CMOS device. However, this approach generally requires additional and more complex processing steps in forming the embedded regions.

In view of the above, there is a need for providing an alternative method to achieve higher magnitudes of stress in the channel (and therefore higher mobility) with the desired type of stress (compressive for PFET and tensile for NFET).

### SUMMARY

The foregoing discussed drawbacks and deficiencies of the prior art are overcome or alleviated, in an exemplary embodiment, by a method of forming a strained metal oxide semiconductor field effect transistor (MOSFET) device including forming a gate conductor and gate insulator layer over a semiconductor substrate; forming source and drain regions in the semiconductor substrate, thereby defining the MOSFET device; forming a phase transformable material layer over the MOSFET device, wherein the phase transformable layer is in a first phase upon initial formation thereof; and following the initial formation of the phase transformable material layer, converting the phase transformable layer from the first phase to a second phase, wherein the second phase results in the phase transformable layer applying a stress on a channel of the MOSFET device.

In another embodiment, a strained metal oxide semiconductor field effect transistor (MOSFET) device includes a gate conductor and gate insulator layer formed over a semiconductor substrate; source and drain regions formed in the semiconductor substrate; a phase transformable material layer formed over the gate conductor and source and drain regions, wherein the phase transformable layer is in a first phase upon initial formation thereof and subsequently converted to a second phase, wherein the second phase results in the phase transformable layer applying a stress on a channel of the MOSFET device.

### BRIEF DESCRIPTION OF THE DRAWINGS

Referring to the exemplary drawings wherein like elements are numbered alike in the several Figures:

FIGS. 1(a) through 1(d) are a sequence of cross sectional views illustrating a method of forming a strained MOSFET device, in accordance with an embodiment of the invention; and

FIGS. 2(a) through 2(d) are a sequence of cross sectional views illustrating a method of forming a strained MOSFET device, in accordance with an alternative embodiment of the invention.

### DETAILED DESCRIPTION

Disclosed herein is a method of forming strained MOSFET devices using phase transformable materials. Briefly stated, the embodiments disclosed herein utilize phase transformation induced stress to improve carrier mobility. A phase transformable material having a first phase is deposited over a transistor device. As a result of a subsequent processing step, such as a thermal anneal, for example, the phase of the phase transformable material changes to a second phase of a different density with respect to the first phase. In so doing, a stress is produced in the material, which is in turn applied to the channel of the underlying transistor device.

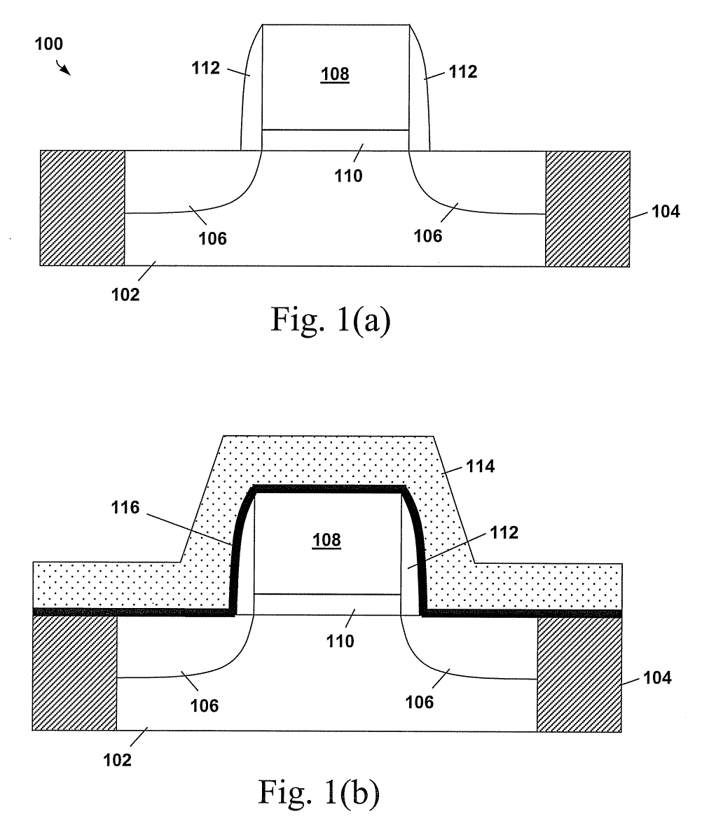

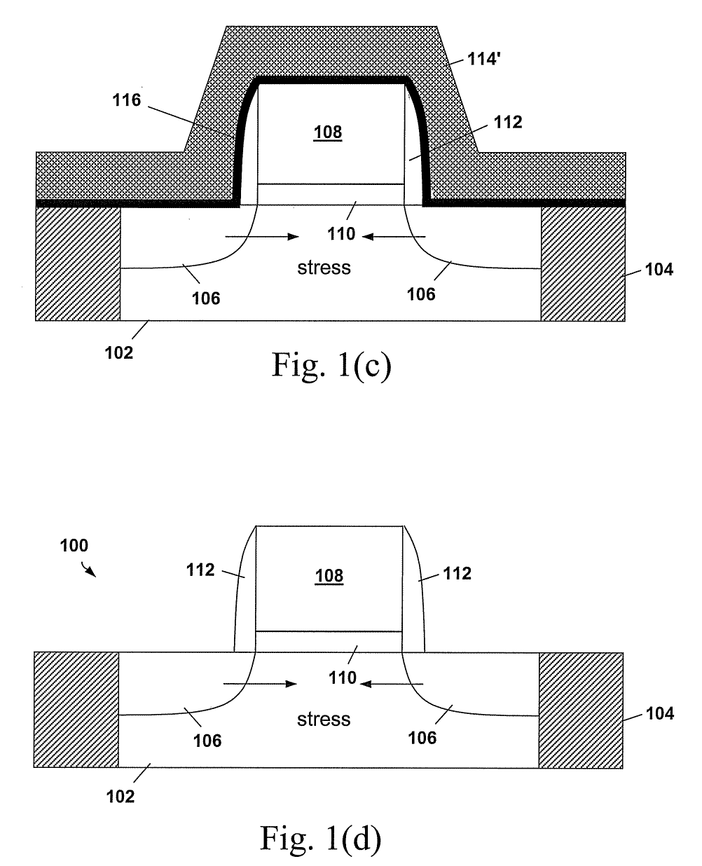

Referring initially to FIGS. 1(a) through 1(d), there is shown a sequence of cross sectional views illustrating a method of forming a strained MOSFET device, in accordance with an embodiment of the invention. As shown in FIG. 1(a), a MOS transistor 100 is formed on a substrate 102, and electrically isolated from other devices (not shown) on the substrate through shallow trench isolation regions 104. In an exemplary embodiment, the substrate 102 may be a semiconductor-on-insulator (SOI) substrate, in which substrate 102 would represent the SOI layer itself (e.g., silicon, germanium, silicon germanium), and wherein a bulk layer (not shown) and a buried oxide (BOX) layer (not shown) formed on the bulk layer would be located below the SOI layer. It should be appreciated, however, that other types of substrates and SOI substrates could also be used in conjunction with the method embodiments disclosed herein. For example, the substrate 100 may be a bulk substrate comprising silicon, germanium, silicon germanium, silicon carbide, or a III-V compound semiconductor (e.g., GaAs), a II-VI compound semiconductors (e.g., ZnSe).

As will further be recognized from FIG. 1(a), the MOS transistor 100 includes doped source/drain regions 106 in the substrate 102, and a gate conductor 108 (e.g., polysilicon and/or metal) formed over a gate insulating layer 110 (e.g., oxide and/or high-k dielectric) on the substrate 102. Sidewall spacers 112 are also shown formed on the sidewall surfaces of the gate conductor 108 and gate insulating layer 110. Then, as shown in FIG. 1(b), a phase transformable material layer 114 is formed over the device. The phase transformable material 114 is in a first phase as initially formed, and is transformed to a second phase during a subsequent processing step. In an exemplary embodiment, the phase transformable material layer 114 includes amorphous silicon (e.g., deposited by chemical vapor deposition (CVD)) that, once annealed, is transformed into polycrystalline silicon. As further shown in FIG. 1(b), an optional liner layer 116 (e.g., oxide or nitride) may be formed prior to the phase transformable material 114 to facilitate subsequent processing.

In FIG. 1(c), the application of external energy to the device (e.g., an annealing step) is used to transform the layer 114 from the first state to the second state (e.g., from amorphous state to the crystalline state), thereafter depicted as layer 114′ in the figures. In so doing, a stress is produced in the crystallized layer 114′ as a result of the density difference between amorphous silicon and crystalline silicon. As particularly shown in FIG. 1(c), the amorphous-to-crystalline phase transformation of layer 114/114′ creates a longitudinal compressive stress in the device channel, thus improving carrier conductivity for PFET devices. In addition, for the specific embodiment depicted, the phase transformation anneal also serves to activate dopant materials in the source and drain regions 106, as well as in the gate conductor 108.

As shown next in FIG. 1(d), both layer 114′ and the optional oxide layer 116 of FIG. 1(c) may be removed, wherein the stress introduced by the phase transformation of layer 114 to 114′ is maintained in (i.e., memorized by) the transistor device 100. Further device processing as known in the art (e.g., gate/source/drain silicide formation, interlevel dielectric (ILD) layer formation, etc.) may then continue. In other embodiments, however, it is contemplated that the phase transformed layer is maintained in the final structure.

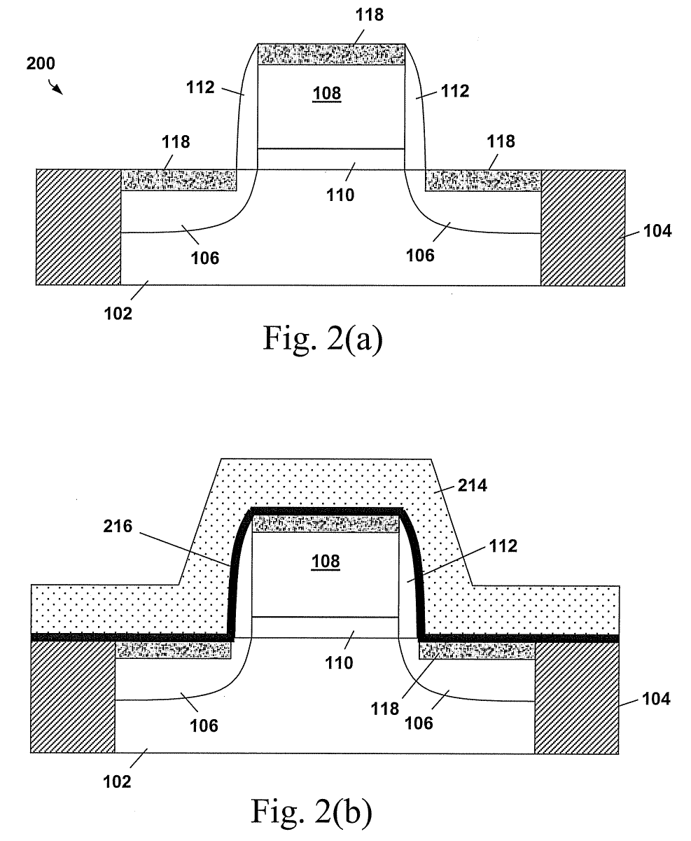

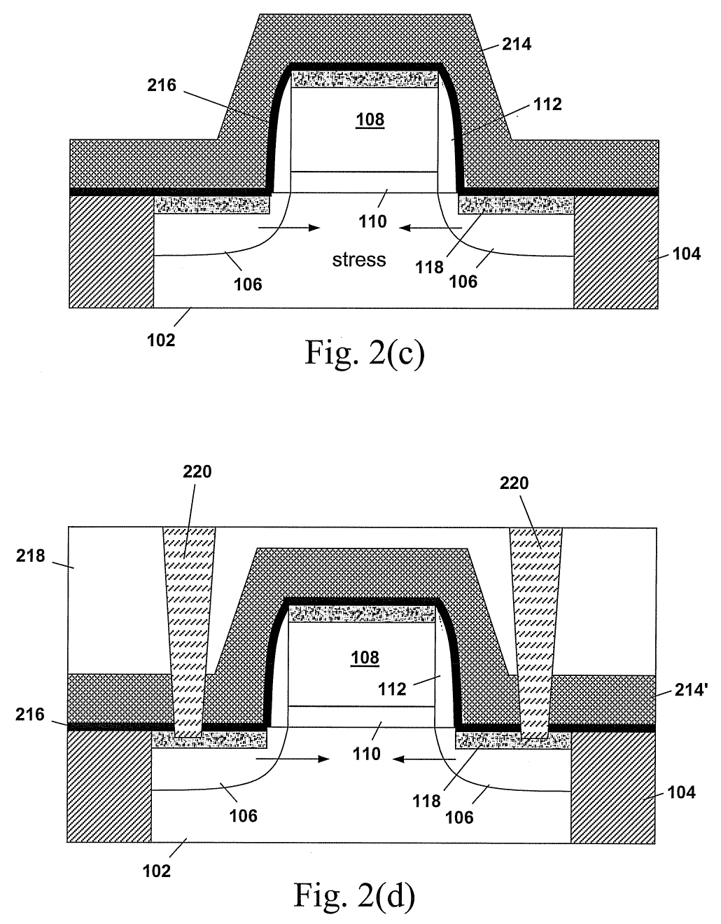

Referring now to FIGS. 2(a) through 2(d), there is shown a sequence of cross sectional views illustrating a method of forming a strained MOSFET device, in accordance with an alternative embodiment of the invention. In the embodiment shown in this sequence, the transistor 200 of FIG. 2(a) includes similar transistor structures as shown in FIG. 1(a), with the addition of silicide contacts 118 already formed on the source and drain regions 106 and the gate conductor 108. As silicide processing is well known in the art, a detailed discussion of the same is omitted.

As then shown in FIG. 2(b), a phase transformable material layer 214 is formed over the device. As with the other embodiment, the phase transformable material 214 is in a first phase as initially formed, and is transformed to a second phase during a subsequent processing step. In an exemplary embodiment, the phase transformable material layer 214 includes an amorphous B₂O₃—TiO₂—SiO₂ glass material that, once annealed, is transformed into a crystalline phase. As further shown in FIG. 2(b), an optional liner layer 216 (e.g., nitride) may be formed prior to the phase transformable material 214 to prevent undesired dopant diffusion from the glass into the underlying transistor device.

In FIG. 2(c), an annealing step is used to transform the glass layer 214 from the first state to the second state (e.g., from amorphous state to the crystalline state), thereafter depicted as layer 214′ in the figures. In so doing, a stress is produced in the crystallized layer 214′ as a result of the density difference between amorphous glass and crystalline glass. As particularly shown in FIG. 2(c), the amorphous-to-crystalline phase transformation of layer 214/214′ creates a longitudinal compressive stress in the device channel, thus improving carrier conductivity for PFET devices. In an alternative embodiment, the phase transformable material layer 214 is initially deposited in a crystalline phase. As a result of a subsequent processing step, such as a laser anneal step, for example, the phase transformable material 214 changes to an amorphous phase (214′) of a different density with respect to the crystalline phase. In so doing, a stress is produced in the amorphous layer 214′. The crystalline-to-amorphous phase transformation of layer 214/214′ creates a longitudinal tensile stress in the device channel, thus improving carrier conductivity for NFET devices.

In addition, for the specific embodiment depicted, the phase transformation anneal also serves to activate dopant materials in the source and drain regions 106, as well as in the gate conductor 108. Finally, as shown in FIG. 2(d), the phase transformed layer 214′ and optional liner layer 216 (e.g., oxide or nitride) is maintained in the device before formation of ILD layer 218 and conductive contacts 220.

It will be appreciated that phase transformable materials described in conjunction with the embodiments described herein are only examples of suitable phase transformable materials that may be used to form strained MOSFET devices, and that still other materials are also contemplated. For example, Germanium-Antimony-Tellurium (i.e., GeSbTe or GST for short) is one phase change material within a group of chalcogenide glass materials (e.g., used in rewritable optical disks) that has a crystallization temperature of less than about 400° C. Still additional amorphous glass materials that crystallize at temperatures below 400° C. may be found in P.W. McMillan, Glass Ceramics, 2^{nd} ed., Academic Press, London, 1979, the contents of which are incorporated by reference herein in their entirety.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of forming a strained metal oxide semiconductor field effect transistor (MOSFET) device, the method comprising:
forming a gate conductor and gate insulator layer over a semiconductor substrate;
forming source and drain regions in the semiconductor substrate, thereby defining the MOSFET device;
forming a phase transformable material layer over the MOSFET device, wherein the phase transformable layer is in a first phase upon initial formation thereof; and
following the initial formation of the phase transformable material layer, converting the phase transformable layer from the first phase to a second phase, wherein the second phase results in the phase transformable layer applying a stress on a channel of the MOSFET device.

2. The method of claim 1, wherein converting the phase transformable layer from the first phase to the second phase comprises performing a thermal anneal of the MOSFET device.

3. The method of claim 2, wherein the first phase is an amorphous phase and the second phase is a crystalline phase.

4. The method of claim 3, wherein a density difference between the amorphous phase and the crystalline phase results in the phase transformable layer applying a compressive stress on a channel of the MOSFET device.

5. The method of claim 2, wherein the phase transformable layer comprises silicon that is initially deposited as amorphous silicon in the first phase and transformed to polycrystalline silicon in the second phase.

6. The method of claim 2, wherein the phase transformable layer comprises a B₂O₃—TiO₂—SiO₂ glass material.

7. The method of claim 2, wherein the phase transformable layer comprises a chalcogenide glass material having a crystallization temperature of less than about 400° C.

8. The method of claim 2, wherein the stress comprises a longitudinal compressive stress.

9. The method of claim 8, wherein the MOSFET device comprises a PFET device.

10. The method of claim 1, wherein converting the phase transformable layer from the first phase to the second phase comprises performing a laser anneal of the MOSFET device.

11. The method of claim 10, wherein the first phase is a crystalline phase and the second phase is an amorphous phase.

12. The method of claim 11, wherein a density difference between the crystalline phase and the amorphous phase results in the phase transformable layer applying a tensile stress on a channel of the MOSFET device.

13. The method of claim 10, wherein the phase transformable layer comprises silicon that is initially deposited as polycrystalline silicon in the first phase and transformed to amorphous silicon in the second phase.

14. The method of claim 10, wherein the stress comprises a longitudinal tensile stress.

15. The method of claim 14, wherein the MOSFET device comprises an NFET device.

16. The method of claim 1, further comprising removing the phase transformable material layer in the second phase, prior to forming silicide contact regions on the gate conductor and source and drain regions, wherein the stress applied to the channel remains following the removal of the phase transformable material layer in the second phase.

17. The method of claim 1, further comprising forming a liner material over the MOSFET device prior to forming the phase transformable layer.

18. The method of claim 17, wherein the liner comprises an oxide.

19. The method of claim 17, wherein the liner comprises a nitride.

20. A strained metal oxide semiconductor field effect transistor (MOSFET) device, comprising:
a gate conductor and gate insulator layer formed over a semiconductor substrate;
source and drain regions formed in the semiconductor substrate;
a phase transformable material layer formed over the gate conductor and source and drain regions, wherein the phase transformable layer is in a first phase upon initial formation thereof and subsequently converted to a second phase, wherein the second phase results in the phase transformable layer applying a stress on a channel of the MOSFET device.
